(19) United States
(12) Patent Application Publication
(10) Pub. No.: US 2014/0155734 A1
(43) Pub. Date: Jun. 5, 2014

(54) METHOD AND PET APPARATUS FOR LOCALIZING AN OBJECT

(71) Applicant: SIEMENS AKTIENGESELLSCHAFT, Munich (DE)

(72) Inventor: Sebastian SCHMIDT, Weisendorf (DE)

(73) Assignee: SIEMENS AKTIENGESELLSCHAFT, Munich (DE)

(21) Appl. No.: 14/079,693

(22) Filed: Nov. 14, 2013

(30) Foreign Application Priority Data
Nov. 30, 2012 (DE) 102012221930.7

(51) Int. Cl. G01R 33/48

(52) U.S. Cl. CPC G01R 33/481
USPC 600/411; 600/425

(57) ABSTRACT

A method for localization of an object in an examination area of an examination object, which includes an organ, is disclosed. In an embodiment, the method includes detection of a repeating movement of the organ in the examination area; detection of PET data of the examination area during the movement; and localization of the object in the examination area by use of the PET data for at least two different repeating movement sections of the movement.

### PRIORITY STATEMENT

The present application hereby claims priority under 35 U.S.C. §119 to German patent application number DE 102012221930.7 filed Nov. 30, 2012, the entire contents of which are hereby incorporated herein by reference.

### FIELD

At least one embodiment of the present invention generally relates to a method and/or a PET apparatus for localizing an object (especially a tumor) in an examination object (especially a human patient), in order to make it easier, depending on the localization, for a doctor to decide on how to proceed in the removal of the object.

### BACKGROUND

An important question in oncology is for example whether a specific tumor (a primary tumor or a metastasis) has already gone beyond a specific organ system or not. With lung tumors for example, if the tumor infiltrates the pleura, this tumor is no longer able to be removed completely by a part resection of the lungs. In this case another treatment strategy is therefore necessary. It is therefore very important for the physician undertaking the treatment to be informed as correctly as possible about the location of the tumor.

According to the prior art, the object is localized as a rule by a combination of PET (Positron Emission Tomography) and CT (Computed Tomography). PET allows malign lesions to be well identified in such cases, and in conjunction with CT with its high spatial resolution, organ boundaries can be well identified, so that the doctor, based on the output of the combination of PET and CT, can make a clear statement about the extent of the tumor.

### SUMMARY

The inventor has recognized that problems occur with small lesions in the prior art. PET in principle exhibits a very high sensitivity and can therefore even localize lesions of just a few 100,000 cells. However CT cannot cleanly image such small lesions. In addition the spatial resolution of the PET is small in this case, and in addition the signal from such small lesions is very weak, so that a poor signal-to-noise ratio makes delineation difficult.

With tumors in the area of the lungs the movement unsharpness effect also comes into play, since breathing movements occur during the PET measurement. In addition it cannot be guaranteed that the PET measurement and the corresponding CT measurement take place in the same breathing position.

The inventor has recognized that the problem therefore exists in accordance with the prior art of a tumor in the area of the lungs only being able to be localized inadequately, so that in accordance with the prior art it cannot be delineated exactly whether the tumor for example is located only within the lungs or whether small portions of the tumor have already gone beyond the boundaries of the organ which, even in the event of these tumor portions being very small, would demand a different therapy strategy than if the entire tumor were to be located only within the lungs.

At least one embodiment of the present invention is directed to a method for localizing an object, and/or a PET apparatus, and/or a computer program product, and/or an electronically-readable data medium. The dependent claims define preferred and advantageous embodiments of the present invention.

A method for localizing an object in a predetermined examination area of an examination object is provided as part of at least one embodiment of the present invention.

In such cases the examination area comprises an organ of the examination object (especially a human patient). At least one embodiment of the inventive method comprises:
Detection of a repeating movement of the organ in the examination area. If the organ involved is the lungs, the repeating movement is the patient's breathing movement (examination object).
Detection of PET data of the examination area during the repeating movement of the organ. As a result PET data of the examination area is detected multiple times during the movement.
Localization of the object (especially of the tumor) in the examination area with the aid of the PET data for a number of different movement sections of the repeating movement. The voxels which belong to the lesion can be detected in such cases by simple threshold value formation of the PET data. (I.e. if a signal derived from the PET data lies above a threshold value the voxel belongs to a lesion and otherwise not.)

A PET apparatus for localizing an object in an examination area of an examination object is also provided as part of an embodiment of the present invention.

In this case the examination area comprises an organ. The PET apparatus possesses a control unit for activating a positron emission detector of the PET apparatus and an image processing unit in order to receive the PET data of the examination area acquired from the positron emission detector. The PET apparatus is embodied to detect a repeating movement of the organ in the examination area in order to acquire the PET data during this movement and to localize the object in the examination area with the aid of the PET data in a number of different movement sections of the movement.

In addition, at least one embodiment of the present invention describes a computer program product, especially a computer program or software, which can be loaded into a memory of a programmable controller or a processing unit of a PET apparatus or of a combined MR/PET device. All or various of the previously described embodiments of the inventive method can be carried out with this computer program product, when the computer program product is running in the controller or control device of the PET apparatus or of the combined MR/PET device. In such cases the computer program product may possibly require program segments/modules, e.g. libraries and auxiliary functions, in order to realize the corresponding embodiments of the method. In other words a computer program or software is especially to be placed under protection with the claim directed to the computer program product, with which one of the embodiments described above of the inventive method can be carried out or which executes this embodiment. In this case the software can involve a source code (e.g. C++) which still has to be compiled (translated) and linked or which only has to be interpreted, or can involve an executable software code which only has to be loaded into the corresponding processing unit for execution.

Finally, at least one embodiment of the present invention discloses an electronically-readable data medium, e.g. a DVD, a magnetic tape or a USB stick, on which the electronically-readable control information, especially software (cf. above) is stored. When this control information (software) is read from the data medium and stored in a controller or processing unit of a PET apparatus or a combined MR/PET device, all inventive embodiments of the previously described method can be executed.

### BRIEF DESCRIPTION OF THE ACCOMPANYING DRAWINGS

The present invention is described below in detail on the basis of example inventive embodiments, which refer to the figures.

FIG. 1 shows a schematic diagram of an embodiment of an inventive combined MR/PET device,

FIG. 2 explains the present invention with reference to three different cases of a tumor in the area of the lungs.

FIG. 3 shows the three cases presented in FIG. 2 in accordance with an embodiment of the invention.

FIG. 4 explains the assignment of PET data to specific movement sections.

FIG. 5 is the inventive diagram of a histogram.

FIG. 6 presents a flow diagram of an embodiment of an inventive method for localization of a lesion.

### DETAILED DESCRIPTION OF THE EXAMPLE EMBODIMENTS

The present invention will be further described in detail in conjunction with the accompanying drawings and embodiments. It should be understood that the particular embodiments described herein are only used to illustrate the present invention but not to limit the present invention.

Accordingly, while example embodiments of the invention are capable of various modifications and alternative forms, embodiments thereof are shown by way of example in the drawings and will herein be described in detail. It should be understood, however, that there is no intent to limit example embodiments of the present invention to the particular forms disclosed. On the contrary, example embodiments are to cover all modifications, equivalents, and alternatives falling within the scope of the invention. Like numbers refer to like elements throughout the description of the figures.

Specific structural and functional details disclosed herein are merely representative for purposes of describing example embodiments of the present invention. This invention may, however, be embodied in many alternate forms and should not be construed as limited to only the embodiments set forth herein.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer, or section from another region, layer, or section. Thus, a first element, component, region, layer, or section discussed below could be termed a second element, component, region, layer, or section without departing from the teachings of the present invention.

In such cases the examination area comprises an organ of the examination object (especially a human patient). At least one embodiment of the inventive method comprises:
Detection of a repeating movement of the organ in the examination area. If the organ involved is the lungs, the repeating movement is the patient's breathing movement (examination object).
Detection of PET data of the examination area during the repeating movement of the organ. As a result PET data of the examination area is detected multiple times during the movement.
Localization of the object (especially of the tumor) in the examination area with the aid of the PET data for a number of different movement sections of the repeating movement. The voxels which belong to the lesion can be detected in such cases by simple threshold value formation of the PET data. (I.e. if a signal derived from the PET data lies above a threshold value the voxel belongs to a lesion and otherwise not.)

In such cases a movement section is to be understood as a periodically repeating movement section of the movement. During a period of the movement each corresponding movement section is executed at least once. If for example the organ periodically moves away from an edge area of the organ and then back towards it again, a first movement section can for example involve that part of the movement during which the organ is at a maximum distance away from the edge area, or a second movement section can involve that part of the movement during which the organ is at a minimum distance away from the edge area.

In other words the object to be localized is localized for at least two different movement sections of the organ in which the object is at least partly assumed or in the vicinity of which the object is assumed. The information contained in the organ movement is accordingly advantageously utilized or evaluated in at least one embodiment of the present invention.

To put it another way, the method does not simply attempt (as is frequently the case in the prior art) to eliminate or to suppress the organ movement as far as possible, but the diagnostic information contained in the organ movement is utilized together with the position of the lesion during the organ movement for precise localization of the lesion in relation to the moving organ. The shift in the lesion over time detected by means of the PET data (during the organ movement) is evaluated for precise localization of the lesion.

In accordance with a preferred inventive embodiment MR data of the examination area is recorded at the same time as the PET data is recorded. In such cases the simultaneous recording of PET data and MR data within the meaning of the present invention also comprises directly sequential or overlapping measurement of MR data and PET data. The MR data can in such cases be recorded by recording with a rapid pulse sequence (e.g. HASTE (“Half fourier Acquisition Single shot Turbo spin Echo”), TRUEFISP (“True Fast Imaging with Steady State Precession”), TurboFlash (“Turbo Fast Low Angle Shot”)), which allows an image rate of several images per second. In such cases the same voxel coordinates of the PET data and MR data correspond to the same anatomical assignments within the examination object. In other words an object localized with the PET data can also be localized within the MR data. Or to put it another way, an object within an image which is created on the basis of the PET data can also be localized within an MR image which is created on the basis of the MR data. The PET data and the MR data can thus be introduced into a common coordinate system.

The periodically repeating movement of the organ can be detected for example with the aid of the MR data. To do this the organ is segmented with the MR data for example so that the movement of the organ is detected together with the movement of the surroundings of the organ. To this end the MR images created from the MR data are registered in each case with a further MR image which is likewise created from the MR data and corresponds to the MR image which follows on in time from the MR image to be registered.

In other words the movement of the organ is tracked as a kind of film with the aid of the MR images created from the MR data and thus the movement of the organ and thereby the division into the different movement sections is detected. For example, to detect the movement of the lungs the position of the diaphragm can be established in each case with the aid of the MR data, or navigator sequences which represent the position of the diaphragm are used.

With an automatic evaluation the (target) organ (for example the lungs) can be segmented in the MR images and the movement of the target organ (the lungs) and the surroundings (the chest wall) can be detected or measured by for example each MR image being elastically registered with the corresponding MR following image and the shift being determined for each voxel (from the MR image to the MR following image). The process is similar for the PET images in that the shift of the (automatically) segmented object (especially the lesion) is tracked. In this way it is possible to determine whether the movement of the object segmented in the PET image takes place in synchrony with the movement of the organ (e.g. the movement of the lungs or the chest wall) or whether parts of the lesion are behaving differently.

The detection of the MR data (MR measurement) can be two-dimensional or three-dimensional in such cases. With a two-dimensional measurement coronal layers are preferably recorded, wherein in the extreme case it is sufficient to work with a single coronal layer which runs through the object to be localized (the lesion) and is recorded repeatedly.

In addition to the quasi-direct detection of the movement of the organ with the aid of the MR data it is also possible in accordance with the invention to indirectly detect the movement of the organ (without detecting MR data) in that a breathing movement or a pulse beat of the examination object is recorded. Depending on this breathing movement or the pulse beat the movement of the organ can then be determined (indirectly).

To display the object, the object can be localized for example for a number of different movement sections of the periodically repeating movement of the organ with the aid of the PET data. The examination area is then shown together with the object which is highlighted accordingly as a type of film throughout a period of time which corresponds to one or more periods of the periodically repeating movement of the organ.

On the basis of this film a doctor can then for example assess the object (the tumor) accordingly.

In accordance with a further inventive embodiment, the PET data is recorded for a number of periods of the repeating movement of the organ. The PET data is assigned to the corresponding movement section in each case. To this end a PET dataset exists for each of these movement sections. The PET data which is recorded during a time interval during which the organ is located in the corresponding movement section will be assigned to the PET dataset corresponding to the movement section. For the respective movement section the object is then localized and/or presented on the basis of the PET data which is located in the PET dataset assigned to the corresponding movement section.

In other words the PET data and if necessary also the MR data are arranged in common time slices with reference to the corresponding movement section (for example in relation to the breathing position). In such cases a number of data set pairs (i.e. PET data and MR data) can be created for the same movement section (e.g. the same breathing position (e.g. with maximum inspiration or expiration). The fact that a number of items of PET data and if necessary MR data are collected enables faults occurring during a movement period to be eliminated by means of averaging or filtering for example. Even with this embodiment the object (e.g. the lesion), starting from the PET data or the corresponding movement section, can be segmented by a simple threshold value formation, wherein this segmentation is then transferred to the MR data, provided this is likewise determined.

In such cases, on the basis of the changing position of the object over the different movement sections, the following cases can be distinguished in the precise localization of the object.
1. The object has two separate spatial positions for one or more movement sections. I.e. the object is split up for the corresponding movement section into two separate parts or subobjects.
2. The object moves synchronously with the movement of the organ for all movement sections.
3. The object moves synchronously with the movement of the organ for no movement section.

If the object involved is a lesion, the cases described above can be interpreted as follows for example for a lesion in the area of the lungs.
1. The lesion divides for a few breathing positions into two individual lesions. In this case tumor cells have generally migrated from one organ (the lungs) into another organ (the pleura), which is also referred to as a so-called “contact metastasis”, which does not form a fixed link to the initial tumor (in the lungs).
2. The lesion shifts synchronously with the organ (the lungs), which indicates that only the lungs (and not the pleura) are affected.
3. The lesion manifests itself in relation to the moving organ (the lungs) and the adjacent organ (the pleura). In this case the lung tumor has grown into the pleura.

To present the PET data a first area of the object or a first area in the vicinity of the object outside the organ can be defined. In addition a second area of the object or a second area in the vicinity of the object inside the organ can be defined. During the movement a displacement of the first area in relation to the second area during the movement is defined.

In other words, the distance between the first area and the second area is determined and presented during the movement of the object. Depending on the manner in which the distance changes during the movement of the organ, the object is localized precisely by a distinction being made as to whether the object is only located within the organ, only outside the organ or partly within and partly outside the organ.

As a further option for presenting the PET data, a distance to the fixed point can be defined for each voxel which is assigned by way of the PET data to the object (i.e. the tumor). In this case the number of these voxels over the distance is presented.

This presentation of the PET data corresponds to the presentation in the form of a histogram which, for all voxels of the object (i.e. the lesion), quasi represents a distribution of the displacement paths.

This presentation too is able to distinguish between the three cases described above.

A PET apparatus for localizing an object in an examination area of an examination object is also provided as part of an embodiment of the present invention.

In this case the examination area comprises an organ. The PET apparatus possesses a control unit for activating a positron emission detector of the PET apparatus and an image processing unit in order to receive the PET data of the examination area acquired from the positron emission detector. The PET apparatus is embodied to detect a repeating movement of the organ in the examination area in order to acquire the PET data during this movement and to localize the object in the examination area with the aid of the PET data in a number of different movement sections of the movement.

In this case the PET apparatus can also involve a combined MR/PET device. The control unit is also embodied here for activating a magnetic resonance system of the MR/PET device, while the image processing unit is also embodied for receiving MR data of the predefined examination area, which is acquired at the same time as the PET data by the magnetic resonance system. The combined MR/PET device is capable of detecting the movement of the organ by way of the MR data.

Advantages of at least one embodiment of the inventive PET apparatus substantially correspond to the advantages of at least one embodiment of the inventive method, which have been described in detail above, so that the description will not be repeated at this point.

In addition, at least one embodiment of the present invention describes a computer program product, especially a computer program or software, which can be loaded into a memory of a programmable controller or a processing unit of a PET apparatus or of a combined MR/PET device. All or various of the previously described embodiments of the inventive method can be carried out with this computer program product, when the computer program product is running in the controller or control device of the PET apparatus or of the combined MR/PET device. In such cases the computer program product may possibly require program segments/modules, e.g. libraries and auxiliary functions, in order to realize the corresponding embodiments of the method. In other words a computer program or software is especially to be placed under protection with the claim directed to the computer program product, with which one of the embodiments described above of the inventive method can be carried out or which executes this embodiment. In this case the software can involve a source code (e.g. C++) which still has to be compiled (translated) and linked or which only has to be interpreted, or can involve an executable software code which only has to be loaded into the corresponding processing unit for execution.

Finally, at least one embodiment of the present invention discloses an electronically-readable data medium, e.g. a DVD, a magnetic tape or a USB stick, on which the electronically-readable control information, especially software (cf. above) is stored. When this control information (software) is read from the data medium and stored in a controller or processing unit of a PET apparatus or a combined MR/PET device, all inventive embodiments of the previously described method can be executed.

At least one embodiment of the present invention evaluates the displacement of the location of a lesion detected on the basis of the PET data relative to an anatomy detected for example with MR data (organ movement) as a diagnostic marker, in order to define the precise location in relation to the moving organ as a function thereof. This advantageously enables the spread of tumors in moveable organs which to be more precisely diagnosed.

At least one embodiment of the present invention is especially suitable for localization of tumors within or in the vicinity of moving organs which move periodically in relation to neighboring organs. Examples of these periodically moving organs are the lungs or the liver, but also the spleen, the kidney or the heart. The present invention is however of course not restricted to this preferred area of application.

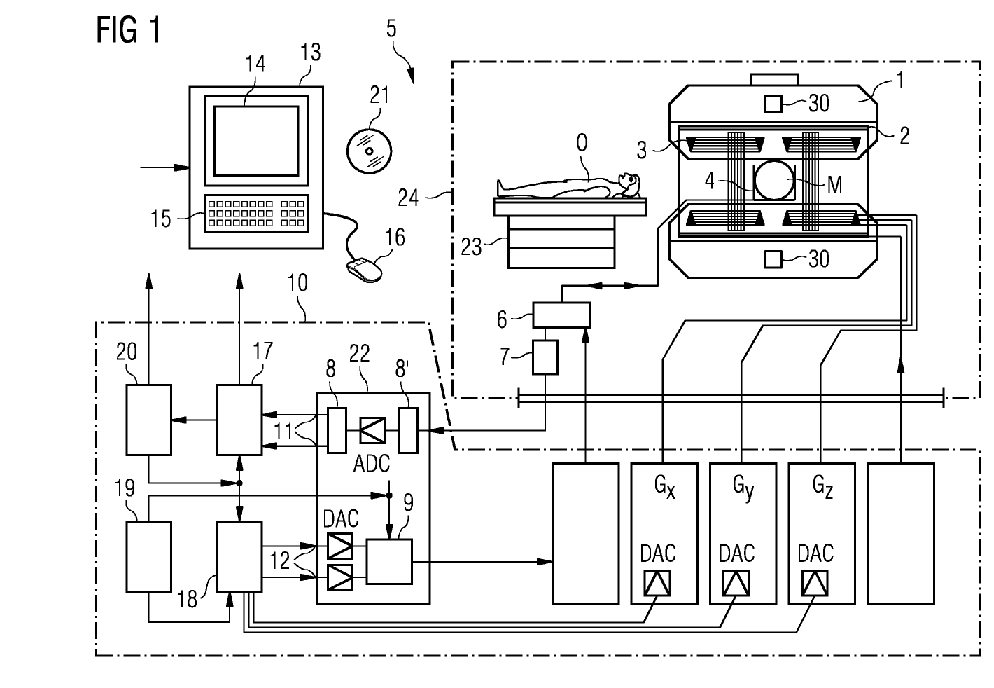

FIG. 1 shows a schematic diagram of a combined MR/PET device 5 having a positron emission detector 30 and a magnetic resonance system 24. In this device a basic field magnet 1 of the magnetic resonance system 24 creates a temporally constant strong magnetic field for polarization or alignment of the nuclear spin in an examination area of an object O, such as for example a part of a human body to be examined, which is pushed, lying on a couch 23, into the magnetic resonance system 24 for creation of an image. The high homogeneity of the basic magnetic field necessary for nuclear resonance measurement is defined in a typically spherical measurement volume M, in which the parts of the human body to be examined are disposed for acquisition of the MR data. To support the homogeneity requirements and especially to eliminate influences which do not vary over time, so-called shims of ferromagnetic material are attached at a suitable point. Influences which vary over time are eliminated by shim coils 2.

A cylindrical gradient coil system 3 which includes three part windings is used in the basic field magnets 1. Each part winding is supplied by an amplifier with current for creating a linear (also temporally variable) gradient field in the respective direction of the Cartesian coordinate system. The first part winding of the gradient field system 3 here creates a gradient Gx in the x-direction, the second part winding creates a gradient Gy in the y-direction and the third part winding creates a gradient Gz in the z-direction. The amplifier includes a digital-analog converter, which is activated by a sequence control 18 to create gradient pulses at the correct time.

One (or more) high-frequency antennas 4 are located within the gradient field system 3, which convert the high-frequency pulses emitted by a high-frequency power amplifier into a magnetic alternating field for exciting the nuclei and aligning the nuclear spin of the object O to be examined or of the area of the object O to be examined. Each high-frequency antenna 4 includes one or more HF transmit coils and one or more HF receive coils in the form of an annular, preferably linear or matrix-shaped arrangement of component coils. The alternating field emitted by the preceding nuclear spin, i.e. as a rule the nuclear spin echo signals obtained from a pulse sequence consisting of one or more high-frequency pulses and one or more gradient pulses, is converted by the HF receive coils of the respective high-frequency antennas 4 into a voltage (measurement signal) which is fed via an amplifier 7 to a high-frequency receive channel 8 of a high-frequency system 22. The high-frequency system 22 further includes a transmit channel 9 in which the high-frequency pulses for the excitation of the magnetic nuclear resonance are created. The respective high-frequency pulses are represented here on the basis of a pulse sequence prespecified by the system processor digitally as a series of complex numbers in the sequence control 18. This number series is supplied as a real and an imaginary part via input 12 in each case to a digital-analog converter in the high-frequency system 22 and from this to a transmit channel 9. In the transmit channel 9 the pulse sequences are modulated up to a high-frequency carrier signal, the basic frequency of which corresponds to the resonance frequency of the nuclear spin in the measurement volume.

The switchover from transmit to receive mode is made via a transceiver switch 6. The HF transmit coils of the high-frequency antenna(s) 4 radiate the high-frequency pulses to excite the nuclear spin in the measurement volume M and resulting echo signals are sampled via the HF receive coil(s). The nuclear resonance signals obtained accordingly are demodulated in the receive channel 8′ (first demodulator) of the high frequency system 22 phase-sensitively to an intermediate frequency and digitized in the analog-digital converter (ADC). This signal is also demodulated to the frequency 0. The demodulation to the frequency 0 and the separation into real and imaginary part takes place after the digitization in the digital domains in a second demodulator 8. An MR image and a PET image (see below) are reconstructed by an image processor 17 from the measurement data thus obtained. The measurement data, the image data and the control programs are administered via the system computer 20. On the basis of a specification with control programs the sequence control 18 checks the creation of the respective desired pulse sequences and the corresponding sampling of the k space. In particular the sequence control 18 controls the correctly-timed switching of the gradients, the transmission of the high-frequency pulses with a defined phase amplitude and the receipt of the nuclear resonance signals in this case. The time base for the high-frequency system 22 and the sequence control 18 is made available by a synthesizer 19.

As has already been stated, the MR/PET device 5 includes a positron emission detector 30, which is mostly embodied in the shape of a ring. The tracers used for PET are marked with a positron emitter. On decay of this positron emitter in the tissue of the patient O, two γ-quantas, which fly away from each other in opposite directions, are created in the vicinity of the location of the corresponding positron emission by an annihilation. If these two γ-quantas are measured by two opposing detector elements of the positron emission detector 30 within a predefined coincidence time interval, the location of the annihilation is defined to a position on the connecting line between these two detector elements.

The PET data is detected with the positron emission detector 30 from which the PET image is then created in the image processor 17. The PET image is combined in accordance with the MR image in the image processor 17 in order to create a combined MR/PET image or to create information combined from PET data and MR data.

The corresponding control programs for creating the MR images, PET images and combined MR/PET image, which are stored on a DVD 21 for example, are selected and the images created are also displayed via a terminal 13 having a keyboard 15, a mouse 16 and a screen 14.

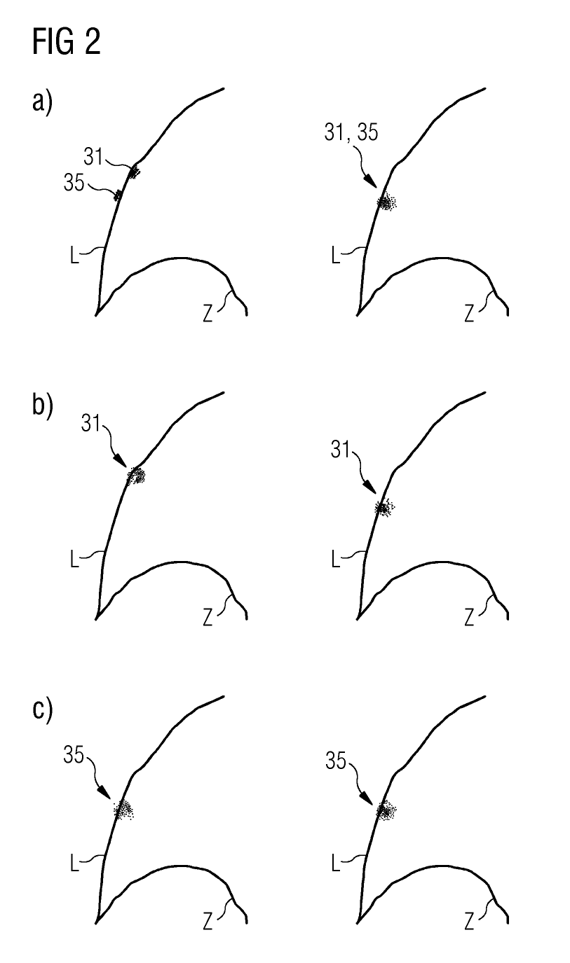

Three different cases (case a) to case c)) for localization of a lesion 31, 35 in the area of the lungs L of a patient are explained with reference to FIG. 2. In these examples FIGS. 2a to 2c each show the lung structure L with the diaphragm Z together with the lesion 31, 35.

In these examples the situation during expiration (breathing out) is shown on the left hand side and the situation during inspiration (breathing in) is shown on the right hand side. It can be seen in FIG. 2a that the lesion splits into two parts 31, 35 during expiration, while the lesion is presented as a one-piece lesion during inspiration. In this case the lesion 35 present outside the lungs L involves a “contact metastasis” which indicates that the tumor cells 35, starting from the lungs L, have migrated into the pleura. However these tumor cells 35 do not form a fixed link to the initial tumor 31 and separate from this initial tumor 31 when the patient O breathes in.

In the case shown in FIG. 2b the lesion 31 moves synchronously with the lungs L. I.e. the location of the lesion 31 differs as a function of which movement section (which breathing position) is being observed. This indicates that only the lungs (and not the pleura) are affected by the lesion 31.

With the case presented in FIG. 2c the lesion 35 does not move as a function of the movement section but the lesion 35 appears fixed. This indicates that the lung tumor 35 has already grown into the pleura.

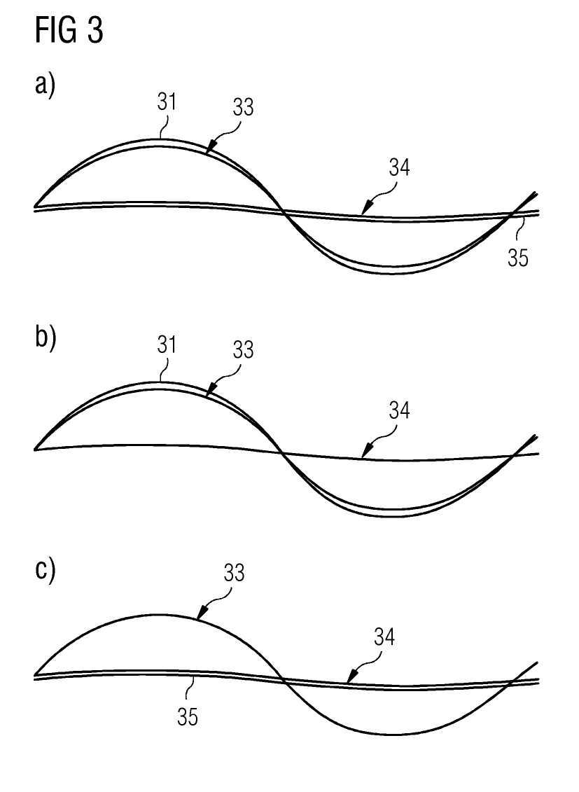

FIGS. 3a to 3c show an embodiment of an inventive option for presenting the localization of the lesion 31, 35 in the area of the lung detected with the PET data. In this case the lesion 31, 35 is localized with the aid of the PET data to numerous different movement sections (breathing positions) and is presented as a type of film during a period of time which corresponds to the duration of a period of the repeating movements of the lungs L.

It can be seen in FIG. 3a that a part 31 of the lesion moves synchronously with the lung tissue 33, while another part 35 of the lesion moves synchronously with the chest wall 34. Therefore the situation presented in FIG. 3a also represents the situation presented in FIG. 2a, in which the lesion 31, 35 splits, depending on the breathing position, into two individual lesions. The curve identified by the reference number 33 or 34 therefore practically shows the local displacement of the lung tissue or of the chest wall.

By contrast with FIG. 3a, in FIG. 3b the lesion 31 only moves synchronously with the lung tissue 33, wherein no part of the lesion follows the movement of the chest wall 34. Therefore the situation depicted in FIG. 3b corresponds to the situation depicted in FIG. 2b in which the lesion 31 is only located within the lungs L.

On the other hand, in FIG. 3c the lesion only moves synchronously with the chest wall 34, which as a result of the small movements of the chest wall 34, can also be seen as it being in a fixed location. The situation depicted in FIG. 3c thus corresponds to the situation also depicted in FIG. 2c, in which the lung tumor 35 has grown into the pleura 34.

The presentation of the timing curve of the lung tissue 33 and of the chest wall 34 is advantageously undertaken in such cases on the basis of MR images which are created from the MR data which is acquired at the same time as the PET data.

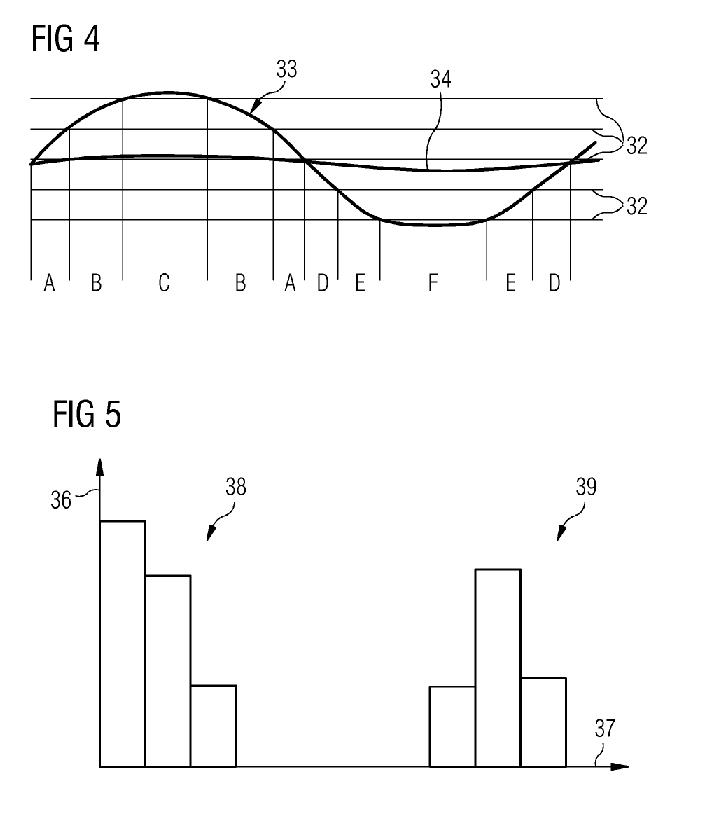

An inventive embodiment is explained with reference to FIG. 4. In this embodiment the PET data is acquired together with data on the basis of which the local displacement of the lung tissue 33 is able to be determined. This local displacement of the lung tissue 33, which can also be referred to as the breathing position, can in such cases be acquired on the basis of an external apparatus (for example a breathing belt or a breathing pillow) or on the basis of MR data which is acquired at the same time as the PET data.

On the basis of this local displacement of the lung tissue 33 a period of the periodically repeating movement of the lungs L is able to be divided into six movement sections A-F with the aid of threshold values 32 for the lung position. That PET data which is acquired while the lungs are located in a specific movement section A-F is assigned to a dataset which is assigned to the corresponding movement section A-F. After all PET data has been assigned to one of the six movement sections A-F, the PET data of each of the six datasets in the example is evaluated in order to determine the location of the lung tumor 31, 35 for the corresponding movement section A-F. Through this corresponding subdivision of the PET data to the different movement sections A-F and the subsequent evaluation of the PET data for localization of the lung tumor the variant of the presentation of the PET data shown in FIG. 3 can be undertaken for instance.

A further inventive embodiment to show the localization of the lesion is explained with the aid of FIG. 5. In this figure, for each voxel which corresponds to a lesion through the evaluation of the PET data, a distance 37 to a fixed point is determined. The corresponding number 36 of these voxels is then plotted as a type of histogram via the distance determined. To put it another way, the histogram shown in FIG. 5 represents the distribution of the displacement distances of the lesion 31, 35 as a result of the movement of the organ.

If for example the lesion splits into two parts, as is the case in the situation presented in FIG. 2a and FIG. 3a, in the histogram shown in FIG. 5 two non-contiguous areas 38, 39 are formed in which the number of voxels is greater for example than in that area which lies between these two areas 38, 39.

On the basis of this histogram the three different cases presented in FIG. 2 or FIG. 3 are also able to be differentiated.

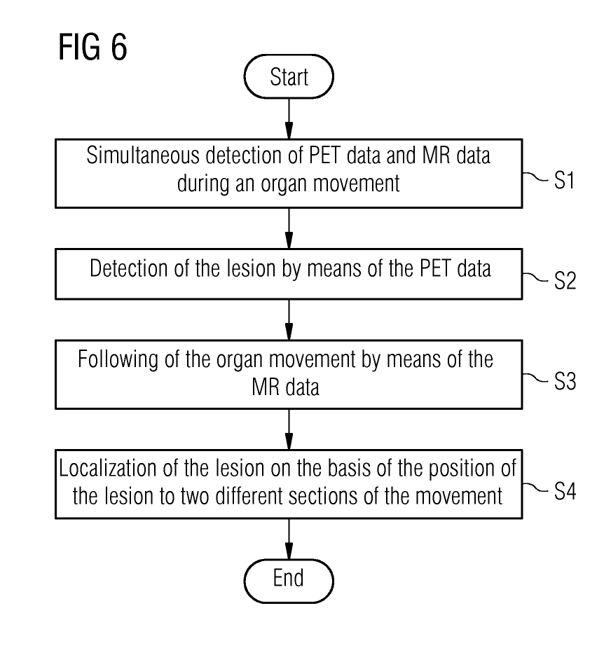

FIG. 6 shows a flow diagram of an embodiment of an inventive method.

In the first step S1 the PET data and the MR data are acquired at the same time during an organ movement (for example the movement of the lungs). A lesion is detected and localized by an evaluation of the PET data in step S2. The organ movement is traced in step S3 by means of the MR data, by for example the organ (the lungs) being segmented in each of the MR images created from the MR data and the movement of the organ traced.

In step S4 the location of the lesion(s) for different movement sections of the movement of the organ is determined and the lesion is localized in relation to the organ as a function of how the location changes depending on the movement. This allows a decision to be made for example as to whether the lesion is only located within the organ (or also outside it) or is only located outside the organ (and not inside it).

Mentioned above are merely example embodiments of the present invention, which are not intended to limit the present invention; and any modifications, equivalent replacements, improvements, etc. made within the spirit and principles of the present invention shall be covered in the protection scope of the present invention.

What is claimed is:

1. A method for localization of an object in an examination area of an examination object, which includes an organ, the method comprising:
detecting a repeating movement of the organ in the examination area;
detecting PET data of the examination area during the movement; and
localizing the object in the examination area by use of the PET data for at least two different repeating movement sections of the movement.

2. The method of claim 1, wherein MR data of the examination area is acquired at the same time as the PET data, so that identical voxel coordinates of the PET data and MR data correspond to the same anatomical assignments within the examination object.

3. The method of claim 2, wherein the movement of the organ is detected with the aid of the MR data.

4. The method of claim 2, wherein the organ is segmented with the MR data in order to detect the movement of the organ together with a movement of an environment of the organ, and wherein each MR image created from the MR data is registered with a further MR image created from the MR data and following the MR image.

5. The method of claim 1, wherein a breathing movement or a pulse beat of the examination object is detected, and depending on the breathing movement or the pulse beat, the movement of the organ is determined indirectly.

6. The method of claim 1, wherein the object is localized by use of the PET data in relation to more than two different movement sections, and wherein the examination area, together with the correspondingly highlighted object, is presented as a type of film during a period which corresponds to one of the repeating movements of the organ.

7. The method of claim 1, wherein the PET data is detected for a number of the repeating movements of the organ, wherein the respective PET data detected, in each case, during a time interval during which the organ moves along a respective specific one of the movement sections is assigned to a PET dataset which corresponds to the respective movement section, and wherein the object is at least one of localized and presented for one of the movement sections on the basis of the PET data of the PET dataset corresponding to the respective movement section.

8. The method of claim 1, wherein the following cases are distinguished for the localization of the object
the object possesses two separate spatial locations for at least a respective one of the movement sections, so that the object has split into two separate subobjects for the respective movement section,
the object moves synchronously with the movement of the organ, and
no part of the object moves synchronously with the movement of the organ.

9. The method of claim 1, wherein a first area of the object or in the vicinity of the object is defined outside the organ, wherein a second area of the object or in the vicinity of the object is defined inside the organ, and wherein a displacement of the first area in relation to the second area during the movement is shown.

10. The method of claim 1, wherein, for each voxel assigned to the object on the basis of the PET data, a distance to a fixed point is determined, and wherein a number of the voxels are shown via the distance.

11. A PET apparatus for localization of an object in an examination area of an examination object, which includes an organ, the PET apparatus comprising:
a control unit configured to activate a positron emission detector of the PET apparatus; and
an image processing unit configured to receive PET data of the examination area acquired by the positron emission detector, wherein the PET apparatus is configured to detect a repeating movement of the organ in the examination area, to acquire the PET data during the movement and to localize the object in the examination area with the aid of the PET data in at least two different movement sections of the movement.

12. The PET apparatus of claim 11, wherein the PET apparatus is a combined MR/PET device, wherein the control unit is also configured to activate a magnetic resonance system of the MR/PET device, wherein the image processing unit is also configured to receive MR data of the examination area recorded by the magnetic resonance system, which is acquired at the same time as the PET data, and wherein the combined MR/PET device is configured, with the aid of the MR data, to detect the movement of the organ.

13. A PET apparatus for localization of an object in an examination area of an examination object, which includes an organ, the PET apparatus comprising:
a control unit configured to activate a positron emission detector of the PET apparatus; and
an image processing unit configured to receive PET data of the examination area acquired by the positron emission detector, wherein the PET apparatus is configured to detect a repeating movement of the organ in the examination area, to acquire the PET data during the movement and to localize the object in the examination area with the aid of the PET data in at least two different movement sections of the movement, wherein the PET apparatus is configured to perform the method of claim 1.

14. A computer program product, loadable directly into a memory of a programmable controller of a PET apparatus, comprising a program including program segments for executing the method of claim 1 when the program is executed in the controller of the PET apparatus.

15. An electronically-readable data medium including electronically-readable control information stored thereon, designed such that, when the data medium is used in a controller of a PET apparatus, it executes the method of claim 1.

16. The method of claim 3, wherein the organ is segmented with the MR data in order to detect the movement of the organ together with a movement of an environment of the organ, and wherein each MR image created from the MR data is registered with a further MR image created from the MR data and following the MR image.
